(19) United States
(12) Patent Application Publication
(10) Pub. No.: US 2022/0367790 A1
(43) Pub. Date: Nov. 17, 2022

(54) NON-VOLATILE MEMORY ELEMENTS FORMED IN CONJUNCTION WITH A MAGNETIC VIA

(71) Applicant: GLOBALFOUNDRIES Singapore Pte. Ltd., Singapore (SG)

(72) Inventors: Vinayak Bharat Naik, Singapore (SG); Kazutaka Yamane, Singapore (SG); Hemant Dixit, Halfmoon, NY (US)

(21) Appl. No.: 17/318,153

(22) Filed: May 12, 2021

(51) Int. Cl. H01L 43/08; H01L 27/22; H01L 43/02; H01L 43/10; H01L 43/12

(52) U.S. Cl. CPC H01L 43/08; H01L 27/228; H01L 43/02; H01L 43/10; H01L 43/12

(57) ABSTRACT

Structures for a non-volatile memory element and methods of forming a structure for a non-volatile memory element. The structure includes a non-volatile memory element having a magnetic-tunneling-junction layer stack. The magnetic-tunneling-junction layer stack has a fixed layer that includes a synthetic antiferromagnetic layer. The structure further includes a via positioned adjacent to the magnetic-tunneling-junction layer stack. The via is comprised of a magnetic material.

### BACKGROUND

The present invention relates to integrated circuits and semiconductor device fabrication and, more specifically, to structures including a non-volatile memory element and methods of forming a structure including a non-volatile memory element.

A magnetoresistive random access memory (MRAM) device provides an embedded non-volatile memory technology in which the memory elements operate based on principles of magnetoresistance. Because its memory elements are non-volatile, the data stored by the magnetoresistive random access memory device is retained when unpowered. The magnetoresistive random access memory device includes multiple bitcells that may be arranged in the rows and columns of an array. Each individual bitcell in the array may include a magnetoresistive memory element and a field-effect transistor that controls access to the magnetoresistive memory element for reading and writing data. Each field-effect transistor may include a gate with a single gate electrode or a gate that includes a pair of gate electrodes. A word line is connected to the gate or gates of the field-effect transistors in each row of the array. The word line may be used to select a column of bitcells for data read and write operations to the associated magnetoresistive memory elements.

Each magnetoresistive memory element may have a layer stack that includes a pinned layer, a free layer, and a thin tunnel barrier layer arranged between the pinned layer and the free layer. The magnetization of the pinned layer is fixed in its magnetic orientation, and the magnetization of the free layer can be switched by, for example, the application of a programming current. In particular, the magnetic orientations of the pinned and free layers may be programmed to have either a parallel state with low electrical resistance across the layers (“0” state) or an antiparallel state with high electrical resistance across the layers (“1” state).

The pinned layer may include a synthetic antiferromagnetic layer having a static magnetic field that can be used to compensate for adverse effects of the magnetic coupling field exerted by the pinned layer on the free layer. In particular, the magnetic coupling field may degrade the switching performance of the free layer. A thick synthetic antiferromagnetic layer may be needed to provide adequate compensation. As the dimensions of the magnetoresistive memory element shrink, the magnetic coupling field increases, which may lead to the need for an even thicker synthetic antiferromagnetic layer. However, thickening the layer stack by thickening the synthetic antiferromagnetic layer may increase the incidence of etch-related shorts, as well as give rise to increased roughness of the tunnel barrier layer that can result in a loss of device durability.

Improved structures including non-volatile memory element and methods of forming a structure including a non-volatile memory element are needed.

### SUMMARY

According to an embodiment of the invention, a structure includes a non-volatile memory element having a magnetic-tunneling-junction layer stack. The magnetic-tunneling-junction layer stack has a fixed layer that includes a synthetic antiferromagnetic layer. The structure further includes a via positioned adjacent to the magnetic-tunneling-junction layer stack. The via is comprised of a magnetic material.

According to an embodiment of the invention, a method includes forming a non-volatile memory element including a magnetic-tunneling-junction layer stack. The magnetic-tunneling-junction layer stack has a fixed layer that includes a synthetic antiferromagnetic layer. The method further includes forming a via positioned adjacent to the magnetic-tunneling-junction layer stack. The via is comprised of a magnetic material.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a magnetoresistive memory element and magnetic via in accordance with embodiments of the invention.

FIG. 2 is a cross-sectional view of a magnetoresistive memory element and magnetic via in accordance with alternative embodiments of the invention.

FIG. 3 is a cross-sectional view of a magnetoresistive memory element and magnetic via in accordance with alternative embodiments of the invention.

FIG. 4 is a cross-sectional view of a layer stack including a magnetoresistive memory element and a magnetic via in accordance with alternative embodiments of the invention.

### DETAILED DESCRIPTION

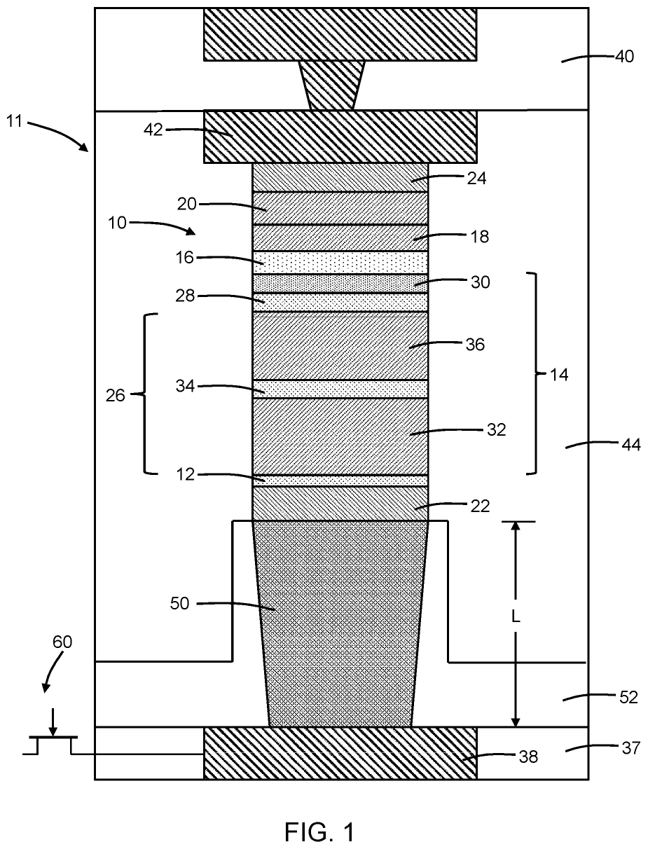

With reference to FIG. 1 and in accordance with embodiments of the invention, a magnetic-tunneling-junction (MTJ) layer stack 10 of a magnetoresistive memory (MRAM) element 11 includes a bottom electrode 22, a seed layer 12, a fixed layer 14, a tunnel barrier layer 16, a free layer 18, a cap layer 20, and a top electrode 24. The layers 12, 14, 16, 18, 20, 22, 24 of the magnetic-tunneling-junction layer stack 10 may be sequentially formed in a vertical arrangement by one or more deposition processes, such as physical vapor deposition processes, and then later patterned.

The bottom electrode 22 may be comprised of a conductor, such as tantalum or tantalum nitride. The seed layer 12, which is positioned on the bottom electrode 22, may enable a smooth and densely-packed deposition and growth of the subsequently-formed layers 14, 16, 18, 20 of the magnetic-tunneling-junction layer stack 10. To that end, the seed layer 12 may contain nickel, chromium, and an additional element, such as ruthenium, that may improve surface smoothness.

The fixed layer 14 may be positioned on the seed layer 12. The fixed layer 14 may include a synthetic antiferromagnetic layer 26, a reference layer 30, and a transition layer 28 that is arranged in a vertical direction between the synthetic antiferromagnetic layer 26 and the reference layer 30. The synthetic antiferromagnetic layer 26 is deposited on the seed layer 12, and then the transition layer 28 and reference layer 30 are sequentially deposited on the synthetic antiferromagnetic layer 26.

The synthetic antiferromagnetic layer 26 may include an antiparallel layer 32 that is positioned on the seed layer 12, an antiparallel layer 36, and a spacer layer 34 that is arranged to separate the antiparallel layer 32 from the antiparallel layer 36. The antiparallel layers 32, 36 may be polarized to have opposite directions of magnetization, and the spacer layer 34 may function to promote pinning of the magnetizations of the antiparallel layers 32, 36. The antiparallel layers 32, 36 may be comprised of a magnetic material, such as multiple bilayers of cobalt and palladium, multiple bilayers of iron and palladium, multiple bilayers of cobalt and platinum, multiple bilayers of iron and platinum, or multiple bilayers of cobalt and nickel. The spacer layer 34 may be comprised of a non-magnetic material, such as ruthenium or molybdenum.

The transition layer 28 of the fixed layer 14 may be comprised of a non-magnetic material, such as tantalum. The transition layer 28 interrupts the crystal structure of the underlying layers 32, 34, 36. Specifically, the transition layer 28 may be an amorphous layer that lacks an organized crystal structure.

The reference layer 30 of the fixed layer 14 may be positioned on the transition layer 28. The reference layer 30 may be highly disordered due to its deposition on the transition layer 28. In an embodiment, the reference layer 30 may be an amorphous layer. In an embodiment, the reference layer 30 may be comprised of a magnetic material, such as a cobalt-iron-boron alloy.

The tunnel barrier layer 16 may be positioned on the reference layer 30 of the fixed layer 14. The tunnel barrier layer 16 may be comprised of a non-magnetic and electrically-insulating dielectric material, such as magnesium oxide or aluminum oxide.

The free layer 18 has a magnetic orientation that may be switched relative to the fixed magnetic orientation of the reference layer 30 during operation of the magnetoresistive memory element 11. The free layer 18 may be positioned on the tunnel barrier layer 16. The tunnel barrier layer 16 is positioned as a separator between the fixed layer 14 and the free layer 18. In an embodiment, the free layer 18 may be an amorphous layer. In an embodiment, the free layer 18 may be comprised of a magnetic material, such as a cobalt-iron-boron alloy.

The cap layer 20 may be positioned on the free layer 18, and the cap layer may be arranged in a vertical direction between the free layer 18 and the top electrode 24. The cap layer 20 may be comprised of ruthenium, tantalum, tungsten, molybdenum, or another suitable metal. The top electrode 24, which is positioned on the cap layer 20, may be comprised of a conductor, such as tantalum or tantalum nitride.

The magnetic-tunneling-junction layer stack 10 is patterned with lithography and etching processes after deposition to impart a given shape to the magnetic-tunneling-junction layer stack 10. The magnetic-tunneling-junction layer stack 10 may be located between wiring levels of an interconnect structure fabricated by back-end-of-line (BEOL) processes. The interconnect structure may include multiple wiring levels that may be formed by deposition, polishing, lithography, and etching techniques characteristic of a damascene process. Specifically, for each wiring level, one or more dielectric layers may be deposited and patterned using lithography and etching processes to define trenches and via openings that are lined with a barrier layer and filled by a planarized conductor to define lines and vias that connect the lines in different wiring levels. Each dielectric layer may be comprised of a dielectric material, such as silicon dioxide or a low-k dielectric material, that is deposited by, for example, chemical vapor deposition.

The wiring level below the magnetic-tunneling-junction layer stack 10 may include a dielectric layer 37 and a metal feature 38. The wiring level above the magnetic-tunneling-junction layer stack 10 may include a dielectric layer 40 and a metal feature 42 that provides a bit line or that is coupled to a bit line. The top electrode 24 of the magnetic-tunneling-junction layer stack 10 is coupled to the metal feature 42. The magnetic-tunneling-junction layer stack 10 is surrounded by a dielectric layer 44. The dielectric layers 37, 40, 44 may be comprised of a carbon-doped oxide dielectric material containing silicon, carbon, oxygen, and hydrogen (SiCOH).

A via 50 is positioned in a vertical direction between the magnetic-tunneling-junction layer stack 10 and the metal feature 38. More specifically, an uppermost portion of the via 50 is positioned adjacent to the bottom electrode 22 and the antiparallel layer 32 of the synthetic antiferromagnetic layer 26, and a lowermost portion of the via 50 is positioned adjacent to the metal feature 38. The via 50 is surrounded by a dielectric layer 52. The dielectric layer 52 may be comprised of a dielectric material, such as silicon dioxide, that is deposited by chemical vapor deposition using tetraethylorthosilicate (TEOS) as a reactant. The via 50 may be formed by patterning an opening in the dielectric layer 52, depositing a magnetic material in the opening, and planarizing the magnetic material before the magnetic-tunneling-junction layer stack 10 is formed. The dielectric layer 52 is recessed adjacent to the via 50 with an etching process following the patterning of the magnetic-tunneling-junction layer stack 10. An encapsulation layer (not shown), which may be comprised of silicon nitride, may be conformally deposited on the recessed dielectric layer 52 and the magnetic-tunneling-junction layer stack 10 before the dielectric layer 44 is deposited.

The via 50 may be comprised of a magnetic material. In an embodiment, the magnetic material may be a magnetic metal. In an embodiment, the magnetic material may be a ferromagnetic metal, which is adapted to be magnetized by an external magnetic field and to remain magnetized after the external magnetic field is removed. In an embodiment, the ferromagnetic metal may be cobalt. In an embodiment, the ferromagnetic metal may include only trace elements in addition to cobalt. In an embodiment, the ferromagnetic metal may be an alloy containing cobalt and another metallic element, such as iron, nickel, platinum, or palladium. Conventional via materials, such as copper, aluminum, and tungsten, are not considered to be suitable material choices for the via 50. The via 50 has a non-layered, one-piece construction as opposed to multiple bilayers found in the construction of the antiparallel layers 32, 36.

In an embodiment, the via 50 may be shaped as a cylinder that is elongated with a long axis oriented in a direction between the metal feature 38 and the magnetic-tunneling-junction layer stack 10. In an embodiment, the via 50 may be shaped as a truncated cone that is elongated with a long axis oriented in a direction between the metal feature 38 and the magnetic-tunneling-junction layer stack 10 and that inversely tapers with a widest portion adjacent to the bottom electrode 22. In an embodiment, the via 50 may have a diameter and a height or length L that is greater than the diameter. In embodiment, the length L of the via 50 may range from 20 nanometers to one micron. In an embodiment, the via 50 may have an length-to-diameter aspect ratio in a range of 3 to 5. The static magnetic field originating from the via 50 may be oriented axially along the length L of the via 50.

In an alternative embodiment, the location of the bottom electrode 22 and via 50 may be swapped such that the via 50 is positioned directly adjacent to the antiparallel layer 32 of the synthetic antiferromagnetic layer 26 and, therefore, between the bottom electrode 22 and the antiparallel layer 32 in a vertical direction.

The magnetoresistive memory element 11 may further include a field-effect transistor 60 that is connected through the interconnect structure with the magnetic-tunneling-junction layer stack 10. The field-effect transistor 60 may be fabricated by front-end-of-line processing on a semiconductor substrate, and a drain of the field-effect transistor 60 may be connected through the metal feature 38 and other features of the interconnect structure with the bottom electrode 22 of the magnetic-tunneling-junction layer stack 10. In particular, the via 50 provides part of the electrical connection of the drain of the field-effect transistor 60 with the magnetic-tunneling-junction layer stack 10.

The magnetic-tunneling-junction layer stack 10 is configured to store data in a non-volatile manner with the assistance of the field-effect transistor 60. Data is stored in the magnetic-tunneling-junction layer stack 10 through different states provided by the relative magnetization orientations of the reference layer 30 of the fixed layer 14 and the free layer 18. The magnetization of the reference layer 30 of the fixed layer 14 has a pinned magnetic orientation that is static or constant, and the magnetization of the free layer 18 can be switched or changed by the application of a directional programming current flowing through the magnetic-tunneling-junction layer stack 10 between the electrodes 22, 24. In particular, a programming current can cause the magnetic orientations of the reference layer 30 of the fixed layer 14 and the free layer 18 to be parallel, giving a lower electrical resistance across the layers (“0” state), or the programming current can cause the magnetic orientations of the reference layer 30 of the fixed layer 14 and the free layer 18 to be antiparallel, giving a higher electrical resistance across the layers (“1” state). The switching of the magnetic orientation of the free layer 18 and the resulting high or low resistance states provide for the write and read operations of the magnetoresistive memory element 11.

The via 50 provides a static magnetic field that compensates for the magnetic coupling field that, if otherwise uncompensated, would degrade the switching performance of the free layer 18 during write operations. Due to the magnetic field provided by the via 50, the thicknesses of the antiparallel layers 32 and 36 of the synthetic antiferromagnetic layer 26 may be reduced. The via 50, which is formed independent of the patterning of the magnetic-tunneling-junction layer stack 10, may reduce the occurrence of etch-related shorts because the magnetic-tunneling-junction layer stack 10 can be thinned due to thinning of the synthetic antiferromagnetic layer 26. The thinner layer stack 10 may also lead to a decrease in the roughness of the tunnel barrier layer 16. The magnetoresistive memory element 11 and via 50 may be replicated and used to fabricate a high-density magnetoresistive random access memory device.

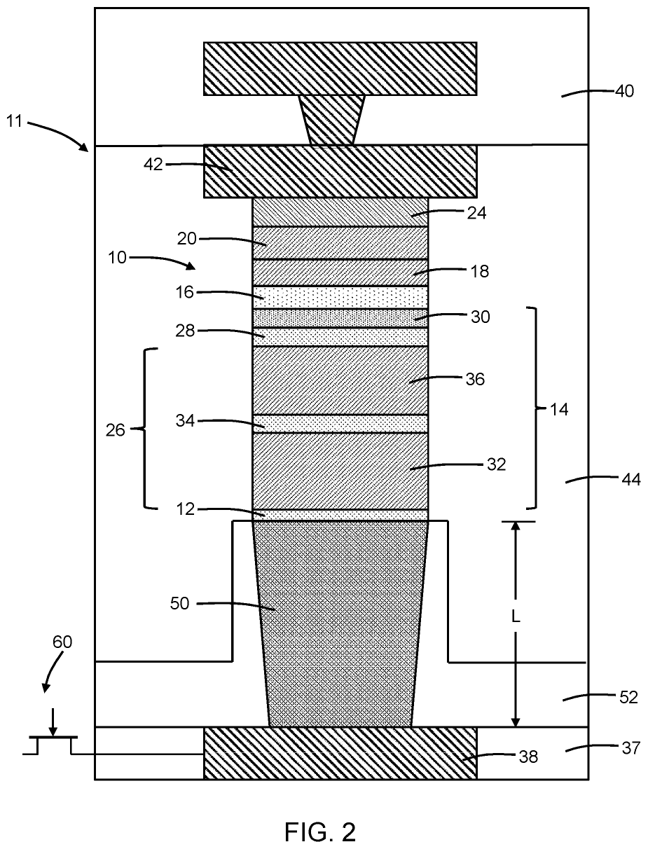

With reference to FIG. 2 in which like reference numerals refer to like features in FIG. 1 and in accordance with alternative embodiments, the bottom electrode 22 may be eliminated such that the via 50 effectively serves as a bottom electrode. In the absence of the bottom electrode 22, the via 50 is positioned in a vertical direction adjacent to the antiparallel layer 32 of the synthetic antiferromagnetic layer 26.

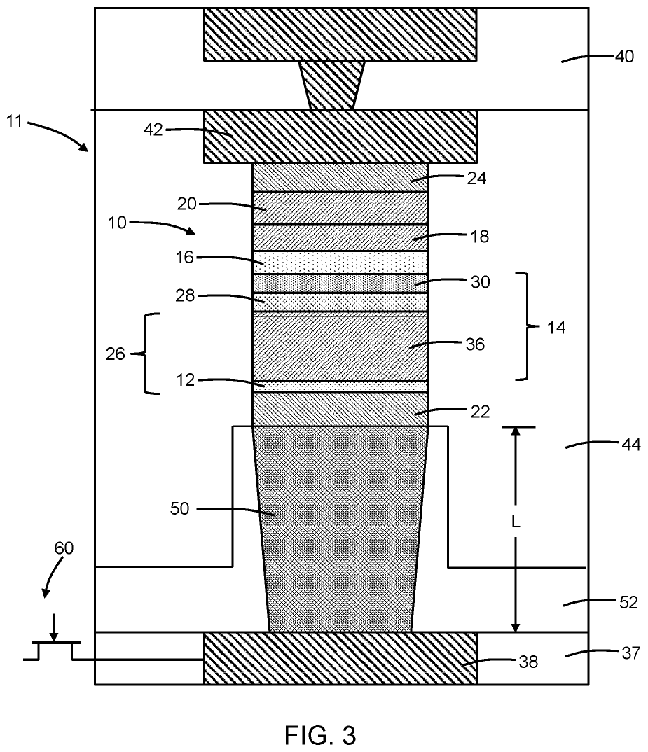

With reference to FIG. 3 in which like reference numerals refer to like features in FIG. 1 and in accordance with alternative embodiments, the magnetic-tunneling-junction layer stack 10 may be modified to eliminate the antiparallel layer 32 such that the synthetic antiferromagnetic layer 26 only includes the antiparallel layer 36. In that regard, the via 50 may be positioned in a vertical direction adjacent to the bottom electrode 22 and the antiparallel layer 36 of the synthetic antiferromagnetic layer 26. The antiparallel layer 36 is positioned between the via 50 and the free layer 18. The magnetic field provided by the via 50 permits a simplification of the synthetic antiferromagnetic layer 26 by providing adequate compensation for the magnetic coupling field with only a single antiparallel layer 36 present in the synthetic antiferromagnetic layer 26.

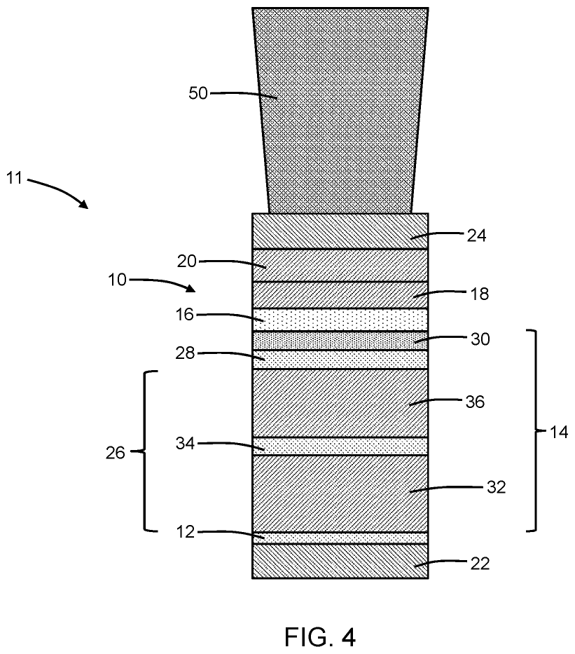

With reference to FIG. 4 in which like reference numerals refer to like features in FIG. 1 and in accordance with alternative embodiments, the via 50 may be positioned over the magnetic-tunneling-junction layer stack 10, instead of being positioned below the magnetic-tunneling-junction layer stack 10. More specifically, the via 50 may be positioned adjacent to the top electrode 24 and the free layer 18. The free layer 18 is positioned in a vertical direction between the via 50 and the synthetic antiferromagnetic layer 26. This rearrangement places the via 50 closer to the free layer 18, which may provide more efficient compensation of the magnetic coupling field.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a non-volatile memory element including a magnetic-tunneling-junction layer stack, the magnetic-tunneling-junction layer stack having a fixed layer that includes a synthetic antiferromagnetic layer; and
a via positioned adjacent to the magnetic-tunneling-junction layer stack, the via comprised of a magnetic material.

2. The structure of claim 1 wherein the magnetic-tunneling-junction layer stack further includes a free layer, and the via is positioned adjacent to the synthetic antiferromagnetic layer.

3. The structure of claim 2 wherein the synthetic antiferromagnetic layer includes a first antiparallel layer, a second antiparallel layer, and a spacer layer positioned between the first antiparallel layer and the second antiparallel layer, and the first antiparallel layer is positioned between the second antiparallel layer and the via.

4. The structure of claim 3 wherein the first antiparallel layer, the second antiparallel layer, and the spacer layer are positioned between the via and the free layer.

5. The structure of claim 2 wherein the synthetic antiferromagnetic layer includes a single antiparallel layer.

6. The structure of claim 5 wherein the single antiparallel layer is positioned between the via and the free layer.

7. The structure of claim 1 wherein the magnetic-tunneling-junction layer stack further includes an electrode, and the electrode is positioned between the via and the synthetic antiferromagnetic layer.

8. The structure of claim 1 further comprising:
a field-effect transistor having a drain connected with the via,
wherein the via connects the drain of the field-effect transistor with the magnetic-tunneling-junction layer stack.

9. The structure of claim 1 wherein the magnetic-tunneling-junction layer stack further includes a free layer, and the via is positioned adjacent to the free layer.

10. The structure of claim 9 wherein the magnetic-tunneling-junction layer stack further includes an electrode, and the electrode is positioned between the via and the synthetic antiferromagnetic layer.

11. The structure of claim 10 wherein the free layer is positioned between the via and the synthetic antiferromagnetic layer.

12. The structure of claim 1 wherein the via is shaped as a cylinder or a cone, and the via has an aspect ratio of length-to-diameter in a range of 3 to 5.

13. The structure of claim 1 wherein the magnetic material is a ferromagnetic metal.

14. The structure of claim 13 wherein the ferromagnetic metal is cobalt.

15. The structure of claim 1 wherein the via has a non-layered, one-piece construction.

16. The structure of claim 1 further comprising:
an interconnect structure including a first wiring level and a second wiring level,
wherein the non-volatile memory element and the via are positioned in the interconnect structure between the first wiring level and the second wiring level.

17. A method comprising:
forming a non-volatile memory element including a magnetic-tunneling-junction layer stack, wherein the magnetic-tunneling-junction layer stack has a fixed layer that includes a synthetic antiferromagnetic layer; and
forming a via positioned adjacent to the magnetic-tunneling-junction layer stack, wherein the via is comprised of a magnetic material.

18. The method of claim 17 wherein the magnetic material is a ferromagnetic metal, and the via has a non-layered, one-piece construction.

19. The method of claim 17 wherein the via is formed after the non-volatile memory element is formed.

20. The method of claim 17 wherein the via is formed before the non-volatile memory element is formed.
